(19) United States
(12) Patent Application Publication
(10) Pub. No.: US 2026/0265906 A1
(43) Pub. Date: Sep. 10, 2026

(54) SEAM FREE MOLYBDENUM GAP FILL

(71) Applicant: Applied Materials, Inc., Santa Clara, CA (US)

(72) Inventors: Changhyun Choi, Santa Clara, CA (US); Kyoung-Ho Bu, Pleasanton, CA (US)

(73) Assignee: Applied Materials, Inc., Santa Clara, CA (US)

(21) Appl. No.: 19/553,615

(22) Filed: Mar. 2, 2026

Related U.S. Application Data
(60) Provisional application No. 63/767,085, filed on Mar. 5, 2025.

(51) Int. Cl. C23C 16/04; C23C 14/14; C23C 14/34; C23C 14/58; C23C 16/14; C23C 16/44; C23C 28/02; H10P 14/43; H10P 14/44; H10W 20/00

(52) U.S. Cl. CPC C23C 16/045; C23C 14/14; C23C 14/34; C23C 14/5873; C23C 16/14; C23C 16/4408; C23C 28/023; H10P 14/43; H10P 14/44; H10W 20/056

(57) ABSTRACT

Embodiments of the disclosure relate to methods for molybdenum gap fill. The method includes forming a metal layer on a substrate surface with at least one feature formed therein by physical vapor deposition (PVD). The substrate surface is then exposed to a molybdenum halide precursor to remove a portion of the metal layer. A molybdenum precursor and a reductant are used to form a gap fill layer within the at least one feature.

### CROSS-REFERENCE TO RELATED APPLICATIONS

This application claims priority to U.S. Provisional Application No. 63/767,085, filed Mar. 5, 2025, the entire disclosure of which is hereby incorporated by reference herein.

### TECHNICAL FIELD

Embodiments of the present disclosure pertain to methods for deposition of molybdenum films within substrate features. More particularly, embodiments of the disclosure are directed to methods which provide gap fill without seams or damage using a passivation-etch-deposition sequence.

### BACKGROUND

Gap fill processes are integral to several semiconductor manufacturing processes. A gap fill process can be used to fill a gap (or feature) with an insulating or conducting material. For example, shallow trench isolation, inter-metal dielectric layers, passivation layers, dummy gate, are all typically implemented by gap fill processes.

As device geometries continue to shrink (e.g., critical dimensions <20 nm, <10 nm, and beyond) and thermal budgets are reduced, defect-free filling of spaces becomes increasingly difficult due to the limitations of conventional deposition processes. Most conventional deposition methods, especially chemical vapor deposition methods, deposit more material on the substrate surface than within the feature, particularly near the bottom of a feature. As a result, the film on the substrate surface must be removed through an etch process after the gap fill deposition is complete. This additional processing step lowers throughput, increasing the cost of manufacture.

Other gap fill methods rely on atomic layer deposition to form metal gap fill materials. These methods typically produce conformal films on all the substrate surfaces. Accordingly, these methods also require an etch of material deposited outside the feature, but they also often produce gap fill with a seam in the middle as films form from the sidewalls and meet in the middle.

Accordingly, there is a need for gap fill methods which allow for greater throughput and deposit in a bottom-up manner to avoid defects in the gap fill.

### SUMMARY

One or more embodiments of the disclosure are directed to a method of depositing molybdenum gap fill. The method comprises: forming a metal layer on a substrate surface with at least one feature formed therein by physical vapor deposition (PVD), the at least one feature having an opening, a sidewall, and extending a depth from a top surface to a bottom surface; exposing the substrate surface to a molybdenum halide precursor to remove a portion of the metal layer; and exposing the substrate surface to a molybdenum precursor and a reductant to form a gap fill layer within the at least one feature.

Additional embodiments of the disclosure are directed to a method of depositing molybdenum gap fill. The method comprises: forming a molybdenum (Mo) layer on a substrate surface with at least one feature formed therein by physical vapor deposition (PVD), the at least one feature having an opening, a sidewall, and extending a depth from a top surface to a bottom surface, and the at least one feature having an aspect ratio greater than or equal to about 100:1; exposing the substrate surface to molybdenum pentachloride (MoCl₅) to remove a portion of the molybdenum (Mo) layer; and exposing the substrate surface to a molybdenum pentachloride (MoCl₅) and a hydrogen (H₂) to form a gap fill layer within the at least one feature.

### BRIEF DESCRIPTION OF THE DRAWINGS

So that the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments. The embodiments, as described herein, are illustrated by way of example and not limitation in the figures of the accompanying drawings in which like references indicate similar elements.

FIG. 1 illustrates a process flow diagram of a deposition method according to one or more embodiments;

FIG. 2A illustrates a cross-sectional view of a substrate during processing according to one or more embodiments;

FIG. 2B illustrates a cross-sectional view of a substrate during processing according to one or more embodiments;

FIG. 2C illustrates a cross-sectional view of a substrate during processing according to one or more embodiments;

FIG. 2D illustrates a cross-sectional view of a substrate during processing according to one or more embodiments;

FIG. 2E illustrates a cross-sectional view of a substrate during processing according to one or more embodiments; and

FIG. 3 illustrates a schematic top-view diagram of an example multi-chamber processing system according to one or more embodiments.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

The term “about” as used herein means approximately or nearly and in the context of a numerical value or range set forth means a variation of ±15% or less, of the numerical value. For example, a value differing by ±14%, ±10%, ±5%, ±2%, ±1%, ±0.5%, or ±0.1% would satisfy the definition of about.

As used in this specification and the appended claims, the term “substrate” and “wafer” are used interchangeably, both referring to a surface, or portion of a surface, upon which a process acts. It will also be understood by those skilled in the art that reference to a substrate can also refer to only a portion of the substrate unless the context clearly indicates otherwise. Additionally, reference to depositing on a substrate can mean both a bare substrate and a substrate with one or more films or features deposited or formed thereon.

A “substrate” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, silicon nitride, doped silicon, germanium, gallium arsenide, glass, sapphire, and any other materials such as metals, metal nitrides, metal alloys, and other conductive materials, depending on the application. Substrates include, without limitation, semiconductor wafers. Substrates may be exposed to a pretreatment process to polish, etch, reduce, oxidize, hydroxylate (or otherwise generate or graft target chemical moieties to impart chemical functionality), anneal and/or bake the substrate surface. In addition to film processing directly on the surface of the substrate itself, in the present disclosure, any of the film processing steps disclosed may also be performed on an underlayer formed on the substrate as disclosed in more detail below, and the term “substrate surface” is intended to include such underlayer as the context indicates. Thus, for example, where a film/layer or partial film/layer has been deposited onto a substrate surface, the exposed surface of the newly deposited film/layer becomes the substrate surface. What a given substrate surface comprises will depend on what films are to be deposited, as well as the particular chemistry used.

As used in this specification and the appended claims, the terms “precursor”, “reactant”, “reactive gas” and the like are used interchangeably to refer to any gaseous species that can react with the substrate surface.

The substrate surface may have one or more features formed therein, one or more layers formed thereon, and combinations thereof. The shape of the feature can be any suitable shape including, but not limited to, peaks, trenches, holes and vias (circular or polygonal). As used in this regard, the term “feature” refers to any intentional surface irregularity. Suitable examples of features include but are not limited to trenches, which have a top, two sidewalls and a bottom extending into the substrate, and vias which have one or more sidewall extending into the substrate to a bottom.

The term “on” indicates that there is direct contact between elements. The term “directly on” indicates that there is direct contact between elements with no intervening elements.

Electronic devices, such as personal computers, workstations, computer servers, mainframes, and other computer related equipment such as printers, scanners and hard disk drives use memory devices that provide substantial data storage capability, while incurring low power consumption. There are two major types of random-access memory cells, dynamic and static, which are well-suited for use in electronic devices. Dynamic random-access memories (DRAMs) can be programmed to store a voltage which represents one of two binary values but require periodic reprogramming or “refreshing” to maintain this voltage for more than very short periods of time. Static random-access memories (SRAM) are so named because they do not require periodic refreshing.

As used herein, the term “dynamic random-access memory” or “DRAM” refers to a memory cell that stores a datum bit by storing a packet of charge (i.e., a binary one), or no charge (i.e., a binary zero) on a capacitor. The charge is gated onto the capacitor via an access transistor and sensed by turning on the same transistor and looking at the voltage perturbation created by dumping the charge packet on the interconnect line on the transistor output. Thus, a single DRAM cell is made of one transistor and one capacitor.

DRAM memory circuits are manufactured by replicating millions of identical circuit elements, known as DRAM cells, on a single semiconductor wafer. Each DRAM cell is an addressable location that can store one bit (binary digit) of data. In its most common form, a DRAM cell consists of two circuit components: a field effect transistor (FET) and a capacitor.

The manufacturing of a DRAM cell includes the fabrication of a transistor, a capacitor, and three contacts: one each to the bit line, the word line, and the reference voltage. Transistors are circuit components or elements that are often formed on semiconductor devices. Depending upon the circuit design, in addition to capacitors, inductors, resistors, diodes, conductive lines, or other elements, transistors are formed on a semiconductor device. Generally, a transistor includes a gate formed between source and drain regions. In one or more embodiments, the source and drain regions include a doped region of a substrate and exhibit a doping profile suitable for a particular application. The gate is positioned over the channel region and includes a gate dielectric interposed between a gate electrode and the channel region in the substrate.

Transistors are circuit components or elements that are often formed on semiconductor devices. Depending upon the circuit design, in addition to capacitors, inductors, resistors, diodes, conductive lines, or other elements, transistors are formed on a semiconductor device. Generally, a transistor includes a gate formed between source and drain regions. In one or more embodiments, the source and drain regions include a doped region of a substrate and exhibit a doping profile suitable for a particular application. The gate is positioned over the channel region and includes a gate dielectric interposed between a gate electrode and the channel region in the substrate.

As used herein, the term “field effect transistor” or “FET” refers to a transistor that uses an electric field to control the electrical behavior of the device. Enhancement mode field effect transistors generally display very high input impedance at low temperatures. The conductivity between the drain and source terminals is controlled by an electric field in the device, which is generated by a voltage difference between the body and the gate of the device. The FET's three terminals are source(S), through which the carriers enter the channel; drain (D), through which the carriers leave the channel; and gate (G), the terminal that modulates the channel conductivity. Conventionally, current entering the channel at the source(S) is designated I_{S} and current entering the channel at the drain (D) is designated I_{D}. Drain-to-source voltage is designated V_{DS}. By applying voltage to gate (G), the current entering the channel at the drain (i.e., I_{D}) can be controlled.

The metal-oxide-semiconductor field-effect transistor (MOSFET) is a type of field-effect transistor (FET). It has an insulated gate, whose voltage determines the conductivity of the device. This ability to change conductivity with the amount of applied voltage is used for amplifying or switching electronic signals. A MOSFET is based on the modulation of charge concentration by a metal-oxide-semiconductor (MOS) capacitance between a body electrode and a gate electrode located above the body and insulated from all other device regions by a gate dielectric layer. Compared to the MOS capacitor, the MOSFET includes two additional terminals (source and drain), each connected to individual highly doped regions that are separated by the body region. These regions can be either p or n type, but they are both of the same type, and of opposite type to the body region. The source and drain (unlike the body) are highly doped as signified by a “+” sign after the type of doping.

If the MOSFET is an n-channel or nMOS FET, then the source and drain are n+ regions and the body is a p region. If the MOSFET is a p-channel or pMOS FET, then the source and drain are p+ regions and the body is a n region. The source is so named because it is the source of the charge carriers (electrons for n-channel, holes for p-channel) that flow through the channel; similarly, the drain is where the charge carriers leave the channel.

As used herein, the term “fin field-effect transistor (FinFET)” refers to a MOSFET transistor built on a substrate where the gate is placed on two or three sides of the channel, forming a double- or triple-gate structure. FinFET devices have been given the generic name FinFETs because the channel region forms a “fin” on the substrate. FinFET devices have fast switching times and high current density.

As used herein, the term “gate all-around (GAA),” is used to refer to an electronic device, e.g., a transistor, in which the gate material surrounds the channel region on all sides. The channel region of a GAA transistor may include nano-wires or nano-slabs, bar-shaped channels, or other suitable channel configurations known to one of skill in the art. In one or more embodiments, the channel region of a GAA device has multiple horizontal nanowires or horizontal bars vertically spaced, making the GAA transistor a stacked horizontal gate-all-around (hGAA) transistor.

As used herein, the term “nanowire” refers to a nanostructure, with a diameter on the order of a nanometer (10⁻⁹ meters). Nanowires can also be defined as the ratio of the length to width being greater than 1000. Alternatively, nanowires can be defined as structures having a thickness or diameter constrained to tens of nanometers or less and an unconstrained length. Nanowires are used in transistors and some laser applications, and, in one or more embodiments, are made of semiconducting materials, metallic materials, insulating materials, superconducting materials, or molecular materials. In one or more embodiments, nanowires are used in transistors for logic CPU, GPU, MPU, and volatile (e.g., DRAM) and non-volatile (e.g., NAND) devices.

As used herein, the term “3D NAND” refers to a type of electronic (solid-state) non-volatile computer storage memory in which the memory cells are stacked in multiple layers. 3D NAND memory generally includes a plurality of memory cells that include floating-gate transistors. Traditionally, 3D NAND memory cells include a plurality of NAND memory structures arranged in three dimensions around a bit line.

In previous approaches, molybdenum (Mo) was conformally deposited using atomic layer deposition (ALD). The ALD deposition created a molybdenum layer on the field, side, and the bottom of the substrate surface, resulting in the formation of seams or voids inside the high aspect ratio feature. Seams and voids are problematic, leading to high resistance and low throughput due to additional gap fill processes required. Other approaches rely upon bottom-up molybdenum deposition using selective etch followed by chemical vapor deposition (CVD) of molybdenum fill, but it was found that this process could lead to molybdenum diffusion into the bottom titanium silicide (TiSix), which can increase contact resistance.

Embodiments of the disclosure advantageously provide methods for depositing molybdenum gap fill in a bottom-up fashion using a passivation-etch-deposition process. Further embodiments advantageously provide methods of depositing gap fill with reduced defects and seams (e.g., voids). The method of one or more embodiments advantageously provides a bottom damage-free (TiSix) process that can ensure low contact resistance. Additionally, there is higher throughput due to in situ processing from etch to bottom-up fill with a reduced number of steps. Furthermore, the method of one or more embodiments provides lower resistance due to the in situ process and, thus, no queue time and no seam inside the feature. And, advantageously, there is a reduced number of steps for capping and pull back.

Without intending to be bound by theory, it is a challenge to achieve bottom-up gap fill of molybdenum (Mo) in a trench structure meeting two criteria at the same time: bottom damage-free and seam-free. One or more embodiments advantageously provides a process scheme to achieve a seam-free and damage-free bottom-up fill of molybdenum (Mo) in a trench structure using PVD molybdenum (Mo), selective etching, and bottom-up molybdenum (Mo) deposition. The method of one or more embodiments can lead to lower contact and bulk resistance due to seam-free characteristics and larger grain expected due to smaller number of nucleation sites.

The embodiments of the disclosure are described by way of the Figures, which illustrate processes and substrates in accordance with one or more embodiments of the disclosure. The processes, schema and resulting substrates shown are merely illustrative of the disclosed processes, and the skilled artisan will recognize that the disclosed processes are not limited to the illustrated applications.

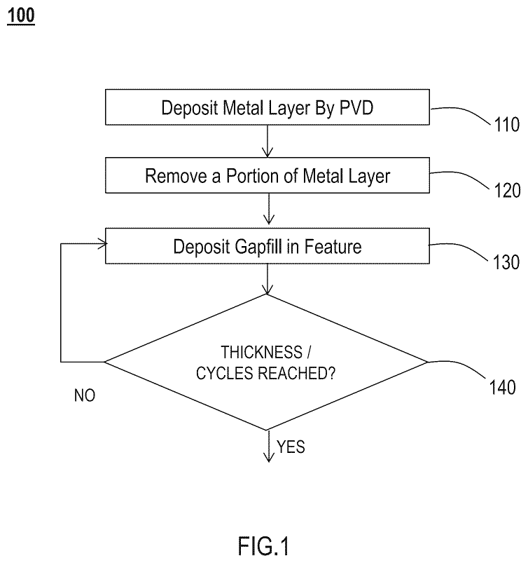

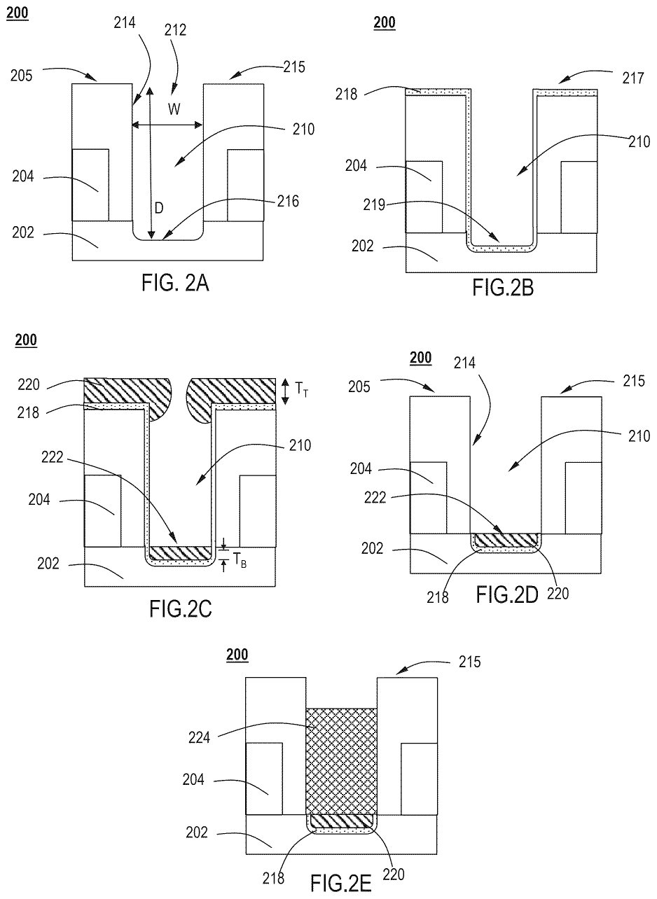

Referring to FIGS. 1-2E, the disclosure relates to a method 100 of depositing a molybdenum gap fill. FIG. 1 depicts a process flow diagram of a deposition method 100 in accordance with one or more embodiments of the present disclosure. FIGS. 2A-2E depict a device 200 during processing according to one or more embodiments of the present disclosure.

FIG. 2A illustrates a device 200 with a substrate surface 205 formed on a substrate 202. As identified above, the substrate surface refers to the exposed surface of the substrate upon which a layer may be formed.

In one or more embodiments, the device 200 has a substrate 202. In one or more embodiments, the semiconductor substrate 202 can be any suitable substrate material. In some embodiments, the substrate 202 may be a bulk semiconductor substrate. As used herein, the term “bulk semiconductor substrate” refers to a substrate in which the entirety of the substrate is comprised of a semiconductor material. The bulk semiconductor substrate may comprise any suitable semiconducting material and/or combinations of semiconducting materials for forming a semiconductor structure. For example, the semiconducting layer may comprise one or more materials such as crystalline silicon (e.g., Si<100> or Si<111>), silicon oxide, strained silicon, silicon germanium, doped or undoped polysilicon, doped or undoped silicon wafers, patterned or non-patterned wafers, doped silicon, germanium, gallium arsenide, or other suitable semiconducting materials. In some embodiments, the semiconductor material is silicon (Si). In one or more embodiments, the semiconductor substrate 202 comprises a semiconductor material, e.g., silicon (Si), carbon (C), germanium (Ge), silicon germanium (SiGe), germanium tin (GeSn), other semiconductor materials, or any combination thereof. In one or more embodiments, the substrate 202 comprises one or more of silicon (Si), germanium (Ge), gallium (Ga), arsenic (As), or phosphorus (P). Although a few examples of materials from which the substrate may be formed are described herein, any material that may serve as a foundation upon which passive and active electronic devices (e.g., transistors, memories, capacitors, inductors, resistors, switches, integrated circuits, amplifiers, optoelectronic devices, or any other electronic devices) may be built falls within the spirit and scope of the present disclosure.

In some embodiments, the semiconductor material may be a doped material, such as n-doped silicon (n-Si), or p-doped silicon (p-Si). In some embodiments, the substrate may be doped using any suitable process such as an ion implantation process. As used herein, the term “n-type” refers to semiconductors that are created by doping an intrinsic semiconductor with an electron donor element during manufacture. The term n-type comes from the negative charge of the electron. In n-type semiconductors, electrons are the majority carriers and holes are the minority carriers. As used herein, the term “p-type” refers to the positive charge of a well (or hole). As opposed to n-type semiconductors, p-type semiconductors have a larger hole concentration than electron concentration. In p-type semiconductors, holes are the majority carriers and electrons are the minority carriers. In one or more embodiments, the dopant is selected from one or more of boron (B), gallium (Ga), phosphorus (P), arsenic (As), other semiconductor dopants, or combinations thereof.

In one or more embodiments, the device 200 includes a gate 204 formed on the substrate. The gate 204 may comprise any suitable materials known to the skilled artisan.

In one or more embodiments, the substrate surface 205 has at least one feature 210 formed therein. The Figures show substrates and devices having a single feature for illustrative purposes; however, those skilled in the art will understand that there can be more than one feature. The shape of the feature 210 can be any suitable shape including, but not limited to, trenches and cylindrical vias. As used in this regard, the term “feature” means any intentional surface irregularity. Suitable examples of features include, but are not limited to, trenches, which have a top, two sidewalls, and a bottom, and peaks, which have a top and two sidewalls. Features can have any suitable aspect ratio (ratio of the depth of the feature to the width of the feature). In some embodiments, the aspect ratio is greater than or equal to about 5:1, greater than or equal to about 10:1, greater than or equal to about 15:1, greater than or equal to about 20:1, greater than or equal to about 25:1, greater than or equal to about 30:1, greater than or equal to about 35:1, greater than or equal to about 40:1, greater than or equal to about 50:1, greater than or equal to about 60:1, greater than or equal to about 70:1, greater than or equal to about 80:1, greater than or equal to about 90:1, or greater than or equal to about 100:1.

In one or more embodiments, the at least one feature 210 comprises an opening between channel layers of a transistor, or memory hole, or a word line slit. Accordingly, in one or more embodiments, the device 200 comprises a memory device or a logic device, e.g., NAND, VNAND, DRAM, GAA, CFET, or the like.

In one or more embodiments, the at least one feature 210 has an opening 212 with a width W. The opening 212 is formed in a top surface 215 of the device 200. The feature 210 also has one or more sidewall 214 and extends a depth D from the top surface 215 to a bottom surface 216. While straight, vertical sidewalls are shown in the Figures, the disclosed methods may also be performed on slanted, irregular, or reentrant sidewalls.

In some embodiments, the width W of the opening 212 is greater than or equal to about 10 nm, greater than or equal to about 15 nm, greater than or equal to about 20 nm, greater than or equal to about 25 nm, greater than or equal to about 30 nm, or greater than or equal to about 35 nm. In some embodiments, the width W is in a range of about 5 nm to about 15 nm, or in a range of about 10 nm to about 35 nm.

In some embodiments, the depth D of the feature 210 is greater than or equal to about 50 nm, greater than or equal to about 75 nm, greater than or equal to about 100 nm, greater than or equal to about 150 nm, greater than or equal to about 200 nm, or greater than or equal to about 250 nm. In some embodiments, the depth D is in a range of about 100 nm to about 200 nm, or in a range of about 200 nm to about 250 nm.

Those skilled in the art will recognize the increasing challenge of depositing metal gap fill in features of narrowing width (also known as critical dimension (CD)) and/or increasing depth. The aspect ratio of the at least one feature 210 is defined as the depth D of the feature 210 divided by the width W. In some embodiments, the at least one feature has an aspect ratio (D:W) greater than or equal to about 20:1, greater than or equal to about 50:1 or greater than or equal to about 100:1.

As identified above, in some embodiments, the device 200 contains a plurality of features 210. Some embodiments of the disclosure advantageously provide molybdenum gap fill for the formation of a DRAM memory cell. Stated differently, in some embodiments, the at least one feature forms a memory cell of DRAM.

Referring to FIG. 2B, in one or more embodiments, a barrier layer 218 is optionally formed on the sidewall 214 and bottom surface 216 of the at least one feature 210. If present, the barrier layer 218 may be formed on the top surface 215 of the substrate surface 205. In one or more embodiments, the barrier layer 218 is a conformal layer. As used herein, the term “conformal” means that the layer adapts to the contours of a feature or a layer. Conformality of a layer is typically quantified by a ratio of the average thickness of a layer deposited on the sidewalls of a feature to the average thickness of the same deposited layer on the field, or upper surface, of the substrate. As used herein, a layer that is “conformally deposited” refers to a layer where the thickness is about the same throughout. A layer which is conformal varies in thickness by less than or equal to about 5%, 2%, 1% or 0.5%. In one or more embodiments, the barrier layer 218 has a conformality greater than 90%, or greater than 91%, or greater than 92%, or greater than 93%, or greater than 94%, or greater than 95%, or greater than 96%, or greater than 97%, or greater than 98%, or greater than 99%.

The barrier layer 218 may comprise any suitable material known to the skilled artisan. In one or more embodiments, the barrier layer 218 comprises one or more of titanium (Ti) and titanium nitride (TiN).

Referring to FIGS. 1 and 2C, the method 100 begins with operation 110. At 110, a metal layer 220 is formed on the top surface 217 of the barrier layer 218, if present, and on the bottom surface 219 of the at least one feature 210. In embodiments where the barrier layer 218 is not present, the metal layer 220 forms on the top surface 215 of the substrate surface 205 and on the bottom surface 216 of the at least one feature 210. In one or more embodiments, the metal layer 220 serves as a passivation layer. In one or more embodiments the sidewall 214 surface of the at least one feature 210 does not form metal layer 220. In one or more embodiments, the metal layer 220 is formed by physical vapor deposition (PVD). In one or more embodiments, the metal layer 220 comprises molybdenum (Mo) which is deposited by PVD. As illustrated in FIG. 2C, PVD leads to deposition of the molybdenum layer primarily on the field (or on the top surface 217 of the barrier layer 218) and bottom surface 219 of the at least one feature 210.

Sputtering is a physical vapor deposition (PVD) process in which high-energy ions impact and erode a solid target and deposit the target material on the surface of a substrate, such as a semiconductor substrate. In semiconductor fabrication, the sputtering process is usually accomplished within a semiconductor fabrication chamber also known as a PVD processing chamber or a sputtering chamber. Sputtering has long been used for the deposition of metals and related materials in the fabrication of semiconductor integrated circuits.

Typically, the sputtering chamber comprises an enclosure wall that encloses a process zone into which a process gas is introduced, a gas energizer to energize the process gas, and an exhaust port to exhaust and control the pressure of the process gas in the chamber. The chamber is used to sputter deposit a material from a sputtering target onto the semiconductor substrate. In one or more embodiments, the material being sputtered comprises molybdenum (Mo). In the sputtering processes, the sputtering target is bombarded by energetic ions, such as a plasma, causing material to be knocked off the target and deposited as a film on the semiconductor substrate.

A typical semiconductor fabrication chamber has a target assembly including disc-shaped target of solid metal or other material supported by a backing plate that holds the target. To promote uniform deposition, the PVD chamber may have an annular concentric metallic ring, which is often called a shield, circumferentially surrounding the disc-shaped target.

Plasma sputtering may be accomplished using either DC sputtering or RF sputtering. Plasma sputtering typically includes a magnetron positioned at the back of a sputtering target including two magnets of opposing poles magnetically coupled at their back through a magnetic yoke to project a magnetic field into the processing space to increase the density of the plasma and enhance the sputtering rate from a front face of the target. Magnets used in the magnetron are typically closed loop for DC sputtering and open loop for RF sputtering.

In some embodiments, as shown in FIG. 2C, the metal layer 220 is deposited by PVD on the top surface 217 of the barrier layer 218 and the bottom surface 219.

In some embodiments, the metal layer 220 has a top thickness T_{T} on the top surface 217 and a bottom thickness T_{B} on the bottom surface 219. In some embodiments, the top thickness T_{T} is greater than the bottom thickness T_{B}. In some embodiments, the top thickness T_{T} is at least 20 Å. In some embodiments, the bottom thickness T_{B} is at least 10 Å. In some embodiments, the bottom thickness T_{B} is in a range of about 10 Å to about 50 Å.

The method 100 continues to operation 120 after formation of the metal layer 220. In some embodiments, the substrate surface 205 is purged of any remaining reactant gases before proceeding to operation 120.

Referring to FIG. 2D, the method 100 continues at operation 120 where the substrate surface 205 is exposed to a molybdenum halide precursor to remove a portion of the metal layer 220. In some embodiments, the thickness of the metal layer 220 on the top surface 215 is reduced by a greater amount than the thickness of the first gap fill on the bottom surface 216. In some embodiments, the metal layer 220 is entirely removed from the top surface 215. In some embodiments, exposure to the molybdenum halide removes a thickness of metal layer 220 in a range of about 10 Å to about 50 Å.

In one or more embodiments, exposing the substrate surface 205 to a molybdenum halide precursor also removes the barrier layer 218 from the field and bottom surface to expose the sidewall 214 of the at least one feature 210. As used herein, the term “halide” refers to a binary phase, of which one part is a halogen atom and the other part is an element or radical that is less electronegative than the halogen, to make a fluoride, chloride, bromide, or iodide compound. A halide ion is a halogen atom bearing a negative charge. As known to those of skill in the art, a halide anion includes fluoride (F—), chloride (Cl—), bromide (Br—), and iodide (I—). Thus, in one or more embodiments, the tungsten halide precursor may comprise any suitable compound containing tungsten (W) and a halide selected from chloride (Cl—), bromide (Br—), and iodide (I—).

The molybdenum halide precursor can be any suitable compound which reacts with the metal layer 220 and the barrier layer 218 to etch/remove the metal layer 220 and the barrier layer 218. In one or more embodiments, the molybdenum halide precursor contains one or more halide ligand. In some embodiments, the molybdenum halide precursor comprises one or more of molybdenum pentachloride (MoCl₅) or molybdenum hexafluoride (MoF₆). In some embodiments, the molybdenum halide precursor consists essentially of molybdenum pentachloride (MoCl₅).

In one or more embodiments, the substrate surface 205 is exposed to a molybdenum halide precursor. After a predetermined quantity of metal layer 220 and the barrier layer 218 have been removed or a predetermined time period of exposure to the molybdenum halide precursor has elapsed, the substrate surface 205 is purged and heated to remove remaining reactant gases, e.g., molybdenum halide precursor, and byproducts. In some embodiments, the purge gas comprises argon (Ar) and hydrogen (H₂). As illustrated in FIG. 2D, the metal layer 220 remains only on the bottom surface 219 of the at least one feature 210. It is noted that the metal layer 220 and the barrier layer 218 (if present) remain after etching. Without intending to be bound by theory, it is thought that the metal layer 220 can then serve as a passivation layer or as a protection layer or as a seed for subsequent gap fill of the at least one feature 210, forming a gap fill layer 224 that is substantially free of seams, voids, or defects.

As used in this regard, “substantially free” means that less than about 5%, including less than about 4%, less than about 3%, less than about 2%, less than about 1%, less than about 0.5%, and less than about 0.1% of the total composition of the conformally deposited metal film (e.g., the gap fill layer 224), on an atomic basis, comprises voids and/or seams.

In some embodiments, the molybdenum halide precursor is delivered from a heated ampoule with a carrier gas. The carrier gas can be any suitable inert gas that does not react with or otherwise alter the metal halide precursor. In one or more embodiments, the carrier gas comprises argon (Ar). In one or more embodiments, the ampoule is heated to a temperature in a range of about 70° C. to 110° C., including in a range of from about 90° C. to about 105° C.

In one or more embodiments, the metal layer 220 is deposited at operation 110 in a non-conformal fashion. In some embodiments, the metal layer 220 is etched at operation 120 in a non-conformal fashion. A “non-conformal fashion” means that the material is deposited or etched with a variable thickness (formed or removed) across the substrate surface 205. For example, in some embodiments, the thickness of the metal layer 220 removed from the bottom surface 216 may be lower than the thickness of the metal layer 220 removed from the top surface 215.

With reference to FIG. 1 and FIG. 2E, at operation 130, a gap fill layer 224 is formed by exposing the substrate surface 205 to a molybdenum precursor and a reductant. In some embodiments, the molybdenum precursor and the reductant are exposed to the substrate simultaneously. In some embodiments, both the molybdenum precursor and the reductant are flowed into the processing space above the substrate constantly. In some embodiments, the molybdenum precursor is flowed constantly while the reductant is pulsed or flowed intermittently.

In one or more embodiments, the molybdenum precursor comprises a molybdenum halide or a molybdenum oxyhalide. In one or more embodiments, the molybdenum precursor comprises or consists essentially of or consists of molybdenum pentachloride (MoCl₅) or molybdenum hexafluoride (MoF₆) embodiments, the molybdenum precursor comprises or consists essentially of molybdenum oxychloride (MoO₂Cl₂). The reductant may be any suitable reductant. In some embodiments, the reductant comprises or consists essentially of hydrogen gas (H₂). As used in this regard, a process gas which “consists essentially of” a stated reactant comprises greater than about 95%, greater than about 98%, greater than about 99%, or greater than about 99.5% of the stated reactant on a molar basis, excluding any inert diluent or carrier gases.

In some embodiments, operation 130 represents a chemical vapor deposition (CVD) process. In some embodiments, the temperature of the CVD process is in a range of about 450° C. to about 600° C., or in a range of about 500° C. to about 600° C. In some embodiments, the CVD process is performed without plasma.

In some embodiments, the molybdenum precursor and the reducing agent have a flow rate ratio in the range of from 1:1000 to 1:10000. Flowing the molybdenum precursor and the reducing agent may result in the formation of a molybdenum monolayer of the gap fill layer 224.

In some embodiments, the substrate surface 205 is exposed to the molybdenum precursor and the reducing agent at any suitable pressure. In one or more embodiments, the pressure is in a range of from 15 Torr to 100 Torr. In more specific embodiments, the range of pressure in the substrate processing chamber, such as a CVD chamber, during deposition of the gap fill layer 224 is in a range of from 15 Torr to 100 Torr.

Referring to FIG. 1, at decision point 140, it is determined whether the gap fill layer 224 has achieved a predetermined thickness. If the deposited gap fill layer 224 has reached a predetermined thickness or a predetermined number of process cycles have been performed, the method 100 moves to an optional post-processing operation 150. If the thickness of the deposited gap fill layer 224 has not reached the predetermined threshold, the method 100 returns to operation 130 to deposit additional gap fill layer 224. The cycle of deposition (operation 130) is repeated until the predetermined thickness of the gap fill layer 224 is achieved.

Referring to FIG. 2E, in one or more embodiments, the cycle of deposition is repeated to fill the entire depth D of the at least one feature 210. In some embodiments, the number of cycles is in a range of about 200 to about 400 cycles or in a range of about 250 to about 350 cycles.

In one or more embodiments, the disclosed methods advantageously form the gap fill layer 224 in a “bottom-up” fashion. A “bottom-up fashion” means that the method 100 accumulates little to no gap fill layer 224 on the top surface 215 and/or the sidewall 214, but rather that the formation of the gap fill layer 224 occurs primarily on the bottom of the at least one feature on a top surface 222 of the metal layer 220. Accordingly, the gap fill layer 224 grows from the bottom of the at least one feature 210 up.

In one or more embodiments, the processing conditions of the method 100 may be controlled. In one or more embodiments, the processing environment is maintained at a predetermined pressure during method 100. In some embodiments, the pressure is maintained in a range of about 5 Torr to about 35 Torr or in a range of about 25 Torr to about 50 Torr.

In one or more embodiments, the substrate is moved from a first chamber to a separate, next chamber for further processing, e.g., at optional operation 150. The substrate can be moved directly from the first chamber to the separate processing chamber, or the substrate can be moved from the first chamber to one or more transfer chambers and then moved to the separate processing chamber. Accordingly, the processing apparatus may comprise multiple chambers in communication with a transfer station. An apparatus of this sort may be referred to as a “cluster tool” or “clustered system”, and the like.

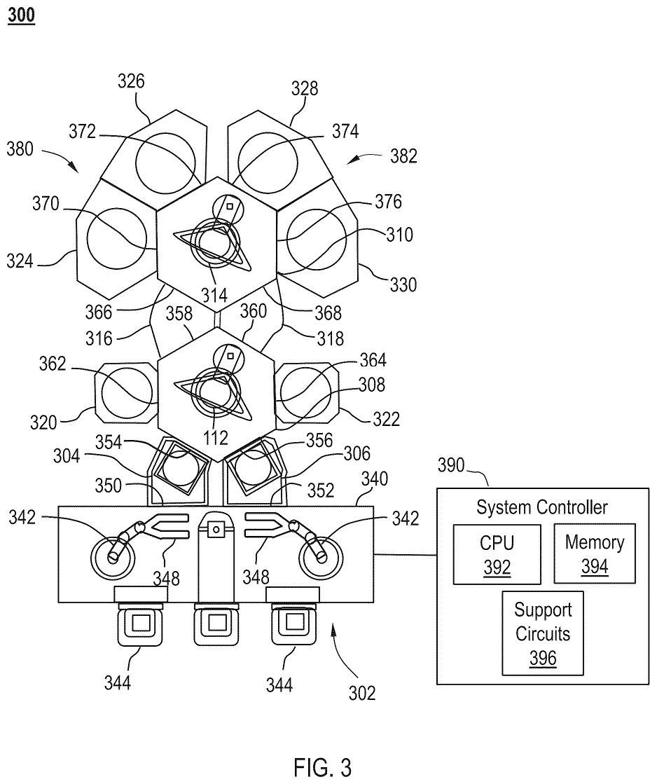

Generally, a cluster tool is a modular system comprising multiple chambers which perform various functions including substrate center-finding and orientation, degassing, annealing, deposition, and/or etching. FIG. 3 is a schematic top-view diagram of an exemplary multi-chamber processing system 300 according to one or more embodiments of the present disclosure. The processing system 300 generally includes a factory interface 302, load lock chambers 304, 306, transfer chambers 308, 310 with respective transfer robots 312, 314, holding chambers 316, 318, and processing chambers 320, 322, 324, 326, 328, 330. As detailed herein, wafers in the processing system 300 can be processed in and transferred between the various chambers without exposing the wafers to an ambient environment exterior to the processing system 300 (e.g., an atmospheric ambient environment such as may be present in a fab). For example, the wafers can be processed in and transferred between the various chambers in a low pressure (e.g., less than or equal to about 300 Torr) or vacuum environment without breaking the low pressure or vacuum environment between various processes performed on the wafers in the processing system 300. Accordingly, the processing system 300 may provide for an integrated solution for some processing of wafers.

In the illustrated example of FIG. 3, the factory interface 302 includes a docking station 340 and factory interface robots 342 to facilitate transfer of wafers. The docking station 340 is configured to accept one or more front opening unified pods (FOUPs) 344. In some examples, each factory interface robot 342 generally comprises a blade 348 disposed on one end of the respective factory interface robot 342 configured to transfer the wafers from the factory interface 302 to the load lock chambers 304, 306.

The load lock chambers 304, 306 have respective ports 350, 352 coupled to the factory interface 302 and respective ports 354, 356 coupled to the transfer chamber 308. The transfer chamber 308 further has respective ports 358, 360 coupled to the holding chambers 316, 318 and respective ports 362, 364 coupled to processing chambers 320, 322. Similarly, the transfer chamber 310 has respective ports 366, 368 coupled to the holding chambers 316, 318 and respective ports 370, 372, 374, 376 coupled to processing chambers 324, 326, 328, 330. The ports 354, 356, 358, 360, 362, 364, 366, 368, 370, 372, 374, 376 can be, for example, slit valve openings with slit valves for passing wafers therethrough by the transfer robots 312, 314 and for providing a seal between respective chambers to prevent a gas from passing between the respective chambers. Generally, any port is open for transferring a wafer therethrough. Otherwise, the port is closed.

The load lock chambers 304, 306, transfer chambers 308, 310, holding chambers 316, 318, and processing chambers 320, 322, 324, 326, 328, 330 may be fluidly coupled to a gas and pressure control system (not specifically illustrated). The gas and pressure control system can include one or more gas pumps (e.g., turbo pumps, cryo-pumps, roughing pumps), gas sources, various valves, and conduits fluidly coupled to the various chambers. In operation, a factory interface robot 342 transfers a wafer from a FOUP 344 through a port 350 or 352 to a load lock chamber 304 or 306. The gas and pressure control system then pumps down the load lock chamber 304 or 306. The gas and pressure control system further maintains the transfer chambers 308, 310 and holding chambers 316, 318 with an interior low pressure or vacuum environment (which may include an inert gas). Hence, the pumping down of the load lock chamber 304 or 306 facilitates passing the wafer between, for example, the atmospheric environment of the factory interface 302 and the low pressure or vacuum environment of the transfer chamber 308.

With the wafer in the load lock chamber 304 or 306 that has been pumped down, the transfer robot 312 transfers the wafer from the load lock chamber 304 or 306 into the transfer chamber 308 through the port 354 or 356. The transfer robot 312 is then capable of transferring the wafer to and/or between any of the processing chambers 320, 322 through the respective ports 362, 364 for processing and the holding chambers 316, 318 through the respective ports 358, 360 for holding to await further transfer. Similarly, the transfer robot 314 is capable of accessing the wafer in the holding chamber 316 or 318 through the port 366 or 368 and is capable of transferring the wafer to and/or between any of the processing chambers 324, 326, 328, 330 through the respective ports 370, 372, 374, 376 for processing and the holding chambers 316, 318 through the respective ports 366, 368 for holding to await further transfer. The transfer and holding of the wafer within and among the various chambers can be in the low pressure or vacuum environment provided by the gas and pressure control system.

The processing chambers 320, 322, 324, 326, 328, 330 can be any appropriate chamber for processing a wafer. In some embodiments, the processing chamber 320 can be capable of performing an annealing process, the processing chamber 322 can be capable of performing a cleaning process, and the processing chambers 324, 326, 328, 330 can be capable of performing epitaxial growth processes. In some examples, the processing chamber 322 can be capable of performing a cleaning process, the processing chamber 320 can be capable of performing an etch process, and the processing chambers 324, 326, 328, 330 can be capable of performing respective epitaxial growth processes. The processing chamber 322 may be any suitable preclean chamber known to the skilled artisan. The processing chamber 320 may be any suitable etch chamber known to the skilled artisan.

A system controller 390 is coupled to the processing system 300 for controlling the processing system 300 or components thereof. For example, the system controller 390 may control the operation of the processing system 300 using a direct control of the chambers 304, 306, 308, 316, 318, 310, 320, 322, 324, 326, 328, 330 of the processing system 300 or by controlling controllers associated with the chambers 304, 306, 308, 316, 318, 310, 320, 322, 324, 326, 328, 330. In operation, the system controller 390 enables data collection and feedback from the respective chambers to coordinate performance of the processing system 300.

The system controller 390 generally includes a central processing unit (CPU) 392, memory 394, and support circuits 396. The CPU 392 may be one of any form of a general-purpose processor that can be used in an industrial setting. The memory 394, or non-transitory computer-readable medium, is accessible by the CPU 392 and may be one or more of memory such as random-access memory (RAM), read only memory (ROM), floppy disk, hard disk, or any other form of digital storage, local or remote. The support circuits 396 are coupled to the CPU 392 and may comprise cache, clock circuits, input/output subsystems, power supplies, and the like. The various methods disclosed herein may generally be implemented under the control of the CPU 392 by the CPU 392 executing computer instruction code stored in the memory 394 (or in memory of a particular process chamber) as, for example, a software routine. When the computer instruction code is executed by the CPU 392, the CPU 392 controls the chambers to perform processes in accordance with the various methods.

Other processing systems can be in other configurations. For example, more or fewer processing chambers may be coupled to a transfer apparatus. In the illustrated example, the transfer apparatus includes the transfer chambers 308, 310 and the holding chambers 316, 318. In other examples, more or fewer transfer chambers (e.g., one transfer chamber) and/or more or fewer holding chambers (e.g., no holding chambers) may be implemented as a transfer apparatus in a processing system.

Processes may generally be stored in the memory of the system controller 390 as a software routine that, when executed by the processor, causes the process chamber to perform processes of the present disclosure. The software routine may also be stored and/or executed by a second processor (not shown) that is remotely located from the hardware being controlled by the processor. Some or all of the methods of the present disclosure may also be performed in hardware. As such, the process may be implemented in software and executed using a computer system, in hardware such as, e.g., an application specific integrated circuit or other type of hardware implementation, or as a combination of software and hardware. The software routine, when executed by the processor, transforms the general-purpose computer into a specific-purpose computer (controller) that controls the chamber operation such that the processes are performed.

Embodiments of the disclosure are directed to a non-transitory computer readable medium. In one or more embodiments, the non-transitory computer readable medium includes instructions that, when executed by a controller of a processing chamber, causes a processing chamber to perform the operations of any of the methods (e.g., deposition method 100) described herein. In one or more embodiments, the controller causes a processing chamber to perform the operations of deposition method 100. In one or more embodiments, the controller causes the processing chamber to perform the operations of depositing a seed layer on a substrate surface having at least one feature therein (operation 110). The at least one feature comprises at least one surface defining a via having a bottom surface and at least one sidewall. In one or more embodiments, the controller causes the processing chamber to perform the operations of exposing to a molybdenum halide precursor to remove a portion of the seed layer (operation 120). In one or more embodiments, the controller causes the processing chamber to perform the operations of exposing the substrate to molybdenum precursor and a reductant to form a first metal gap fill within the at least one feature (operation 130).

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” may encompass both an orientation of above and below. The device may be otherwise oriented (rotated 90 degrees or at other orientations) and the spatially relative descriptors used herein interpreted accordingly.

The use of the terms “a” and “an” and “the” and similar referents in the context of describing the materials and methods discussed herein (especially in the context of the following claims) are to be construed to cover both the singular and the plural, unless otherwise indicated herein or clearly contradicted by context. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the materials and methods and does not pose a limitation on the scope unless otherwise claimed. No language in the specification should be construed as indicating any non-claimed element as essential to the practice of the disclosed materials and methods.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. In one or more embodiments, the particular features, structures, materials, or characteristics are combined in any suitable manner.

Although the disclosure herein has been described with reference to particular embodiments, it is to be understood that these embodiments are merely illustrative of the principles and applications of the present disclosure. It will be apparent to those skilled in the art that various modifications and variations can be made to the method and apparatus of the present disclosure without departing from the spirit and scope of the disclosure. Thus, it is intended that the present disclosure includes modifications and variations that are within the scope of the appended claims and their equivalents.

What is claimed is:

1. A method of depositing molybdenum gap fill, the method comprising:
forming a metal layer on a substrate surface with at least one feature formed therein by physical vapor deposition (PVD), the at least one feature having an opening, a sidewall, and extending a depth from a top surface to a bottom surface;
exposing the substrate surface to a molybdenum halide precursor to remove a portion of the metal layer; and
exposing the substrate surface to a molybdenum precursor and a reductant to form a gap fill layer within the at least one feature.

2. The method of claim 1, wherein the metal layer forms on the top surface of the at least one feature and on the bottom surface of the at least one feature.

3. The method of claim 2, wherein the metal layer is removed from the top surface of the at least one feature.

4. The method of claim 1, wherein the at least one feature has an aspect ratio greater than or equal to about 50:1.

5. The method of claim 2, wherein the at least one feature has an aspect ratio greater than or equal to about 100:1.

6. The method of claim 1, wherein the at least one feature forms a memory cell of DRAM.

7. The method of claim 1, wherein the molybdenum halide precursor comprises one or more of molybdenum pentachloride (MoCl₅) or molybdenum hexafluoride (MoF₆).

8. The method of claim 1, wherein the gap fill layer is formed by a CVD process.

9. The method of claim 8, wherein the CVD process is performed without plasma.

10. The method of claim 1, wherein the molybdenum precursor comprises an oxyhalide.

11. The method of claim 10, wherein the molybdenum precursor comprises one or more of molybdenum pentachloride (MoCl₅), molybdenum hexafluoride (MoF₆), or molybdenum oxychloride (MoO₂Cl₂).

12. The method of claim 1, wherein the method forms the gap fill layer in a bottom-up fashion.

13. The method of claim 1, wherein the gap fill layer is substantially free of voids.

14. The method of claim 1, wherein the substrate surface is purged after exposure to the molybdenum halide precursor.

15. The method of claim 1, wherein the metal layer comprises molybdenum (Mo).

16. The method of claim 1, wherein the gap fill layer comprises molybdenum (Mo).

17. The method of claim 1, wherein the substrate surface comprises a barrier layer thereon, and wherein the barrier layer is removed by the molybdenum halide precursor.

18. The method of claim 17, wherein the barrier layer comprises one or more of titanium (Ti) and titanium nitride (TiN).

19. A method of depositing molybdenum gap fill, the method comprising:
forming a molybdenum (Mo) layer on a substrate surface with at least one feature formed therein by physical vapor deposition (PVD), the at least one feature having an opening, a sidewall, and extending a depth from a top surface to a bottom surface, and the at least one feature having an aspect ratio greater than or equal to about 100:1;
exposing the substrate surface to molybdenum pentachloride (MoCl₅) to remove a portion of the molybdenum (Mo) layer; and
exposing the substrate surface to a molybdenum pentachloride (MoCl₅) and a hydrogen (H₂) to form a gap fill layer within the at least one feature.

20. The method of claim 19, wherein the substrate surface comprises a barrier layer thereon, and wherein the barrier layer is removed by the molybdenum pentachloride (MoCl₅).
